(19) United States
(12) Patent Application Publication
(10) Pub. No.: US 2017/0121600 A1
(43) Pub. Date: May 4, 2017

(54) Phosphor, Light-Emitting Device Containing a Phosphor and Method for Producing a Phosphor

(71) Applicants: Zhongshi Liu, Shanghai (CN); Tianyong Liu, Beijing (CN); Xiping Jing, Beijing (CN)

(72) Inventors: Zhongshi Liu, Shanghai (CN); Tianyong Liu, Beijing (CN); Xiping Jing, Beijing (CN)

(21) Appl. No.: 15/319,691

(22) PCT Filed: Jun. 17, 2014
(86) PCT No.: PCT/CN2014/080056

§ 371 Date: Dec. 16, 2016

(51) Int. Cl. C09K 11/66; H01L 33/50

(52) U.S. Cl. CPC C09K 11/666; H01L 33/502; H01L 2933/0041

(57) ABSTRACT

A phosphor is described. In an embodiment a phosphor includes the material Ca(Al_{12-x-y-z}MgₓGe_{y})O₁₉:(zMn⁴⁺), wherein 0<x, y, z<1. Furthermore, a light-emitting device containing the phosphor and a method for producing the phosphor are also described.

This patent application is a national phase filing under section 371 of PCT/CN2014/080056, filed Jun. 17, 2014 and is incorporated herein by reference in its entirety.

### TECHNICAL FIELD

A phosphor, a light-emitting device containing the phosphor and a method for producing the phosphor are described.

### BACKGROUND

In comparison to conventional incandescent and discharge light sources, a light-emitting diode (LED) provides the advantages of energy saving, long lifetime and color control so that the use of LEDs is continuously expanding as part of a trend toward a more ecologically compatible technology. In a great amount of LED applications, phosphors are used to convert ultraviolet to blue light, that is to say light with spectral components in at least one of an ultraviolet, near ultraviolet and blue wavelength region, to light with longer wavelengths in order to generate white light. The design and the development of new phosphors for LED applications is therefore of great interest.

Compared with phosphors usually used in conventional lamps, an LED phosphor should be excitable in the blue to ultraviolet spectral range and should provide a high quantum efficiency in order to meet the high efficiency of the LED light sources. Temperature quenching should be avoided so that the brightness does not significantly decrease with increasing temperatures and the color coordinate of the white light does not change significantly. Furthermore, the stability of an LED phosphor should match the long lifetime of LED lighting systems, which means for instance that brightness degradation due to ageing effects should be much smaller compared to conventional lamp phosphors. Moreover, the LED phosphor should not be sensitive to humidity and other potentially environmental-deteriorating substances.

### SUMMARY OF THE INVENTION

Embodiments of the invention provide a phosphor that can be used in connection with light-emitting diodes and that emits red light. Further embodiments provide a light-emitting device containing the phosphor and a method for producing the phosphor.

According to at least one embodiment, a phosphor, which can be used for instance in connection with a light-emitting diode, comprises the material Ca(AlMgGe)₁₂O₁₉:Mn⁴⁺. The phosphor is therefore based on the Mn⁴⁺ activated material system CaAl₁₂O₁₉, wherein the material is modified by adding Mg and Ge to the crystal lattice. In particular, the phosphor comprises Ca(Al_{12-x-y-z}MgₓGe_{y})O₁₉:(zMn⁴⁺), with x, y, z denoting the respective mole fractions of Mg, Ge and Mn and 0<x, y, z<1. Furthermore, the phosphor can consist of Ca(Al_{12-x-y-z}MgₓGe_{y})O₁₉:(zMn⁴⁺).

Here and in the following, quantitative specifications of parameters such as, for example, numerical values of fractions of atoms in the herein-described phosphor can include deviations of equal to or less than 30% or equal to or less than 20% or equal to or less than 10% around the given numerical values.

According to at least one further embodiment, the modified Mn⁴⁺ activated CaAl₁₂O₁₉ based phosphor described herein is suitable and embodied to be able to absorb light in an ultraviolet to blue wavelength range, that is to say, as mentioned above, light with spectral components in at least one of an ultraviolet, near ultraviolet and blue wavelength region, and to emit red light with spectral components at least in a wavelength range of about 600 nm to 700 nm. Such absorption and emission behavior can be very advantageous in connection with LED applications using an ultraviolet to blue light-emitting semiconductor layer sequence. In particular, the absorption can, for example occur, around 460 nm. Moreover, upon excitation of the phosphor light can be emitted by the phosphor with a peak wavelength in a wavelength range of 650 nm to 660 nm, in particular around 656 nm.

Compared, for example, to fluoride-based materials, the oxide-based host material of the herein-described phosphor can provide a high stability, is hardly degraded by usual environmental conditions and does not emit toxic elements into the environment. As described below, the manufacturing process does not require special tools, high pressure and a special atmosphere, and rather cheap raw materials can be used so that the phosphor described herein can be produced at a rather low cost. Compared to red phosphors based on nitrides and oxynitrides, the phosphor described herein can provide a better monochromaticity, since the Mn⁴⁺ centers provides a narrow band emission, also denoted as linear emission.

According to at least one further embodiment, the Mg atoms, which have the oxidation state 2+, as well as the Ge atoms, which have the oxidation state 4+, replace Al atoms in the crystal lattice with the oxidation state 3+. For example in connection with the Mg atoms, the inventors have found that it is particularly advantageous when the Mg²⁺ replaces Al³⁺ sites rather than Ca²⁺ sites. This may be due to the fact that the Mn⁴⁺ also replaces the Al³⁺ sites, which can cause a distortion in crystal. Such distortion can in turn be reduced by using Mn⁴⁺ in combination with Mg²⁺, since due to the Mg²⁺ the crystal field is adapted to be more suitable for the Mn⁴⁺ dopant and the conversion performance can be increased. The inventors have also found out that a further improvement can be achieved not only by inserting Mg atoms, but by additionally inserting Ge atoms in the crystal lattice, since by the insertion of Ge⁴⁺ in the crystal lattice, the crystal field is further modified and thus even more suitable for the Mn⁴⁺ dopant, which further enhances the conversion performance. It has been found that Ge is particularly advantageous in connection with Mg for modifying the CaAl₁₂O₁₉ crystal lattice. Thus, compared to an unmodified CaAl₁₂O₁₉:Mn⁴⁺ phosphor and to a Ca(AlMg)₁₂O₁₉:Mn⁴⁺ phosphor, the phosphor described herein, which additionally contains Ge, provides a higher efficiency and thus a better conversion performance.

According to at least one further embodiment, in a method for producing a phosphor comprising Ca(Al_{12-x-y-z}MgₓGe_{y})O₁₉:(zMn⁴⁺), raw materials are provided. In particular, the method is suitable for producing the phosphor as solid solution, preferably in a single solid-state phase, also denoted as a pure phase. Moreover, the production conditions, for example the raw materials, their relative concentrations and the processing conditions, can be chosen in such way that Mg and Ge atoms substitute Al atoms in the crystal lattice, as described before. In the following, an exemplary method for reaching that goal is described.

The features and embodiments described before and in the following relate to both the phosphor and the method for producing the phosphor, respectively.

According to at least one further embodiment, Al(OH)₃, CaCO₃, Mg(OH)₂.4MgCO₃.6H₂O, MnO₂ and GeO₂ are provided as raw materials. Preferably, the raw materials are provided with high purity. In a further method step, the raw materials can be weighted and provided in a suitable amount according to the stoichiometric composition of the phosphor to be produced.

According to at least one further embodiment, the raw materials are milled and a mixed powder is formed. For example, the raw materials can be milled in a crucible such as an agate crucible. In order to provide a well-mixed powder, the milling can be performed for a certain time, for example for at least 30 minutes.

According to at least one further embodiment, the raw materials, preferably as mixed powder, are heated together. The heating procedure can also be denoted as firing. For the heating process, the raw materials, in particular the mixed powder of the raw materials, which can be put into a heat resistant crucible such as, for example, an Al₂O₃ crucible, can be heated in a furnace.

According to at least one further embodiment, the raw materials, preferably as mixed powders, are heated together to a temperature of at least 1500° C., preferably to a temperature of at least 1550° C. and more preferably to a temperature of at least 1600° C. When the target temperature is reached, it can be maintained for a certain time, for example for at least 4 hours. During this time the raw materials form a solid solution which preferably has a pure phase. The product received by the heating process, which is the phosphor material described herein, can be milled again in order to obtain a powder of the produced phosphor.

According to at least one further embodiment, the molar fraction x of Mg is equal to or greater than 0.01, or equal to or greater than 0.02, or equal to or greater than 0.03. Furthermore, the molar fraction x of Mg can be equal to or smaller than 0.10, or equal to or smaller than 0.8, or equal to or smaller than 0.6, or equal to or smaller than 0.5. In a particularly preferred embodiment, x is equal to 0.04.

According to at least one further embodiment, the molar fraction y of Ge is equal to or greater than 0.001, or equal to or greater than 0.002, or equal to or greater than 0.005, or equal to or greater than 0.007. Furthermore, the molar fraction y of Ge can be smaller than 0.016, or equal to or smaller than 0.015, or equal to or smaller than 0.012, or equal to or smaller than 0.010, or equal to or smaller than 0.009. In a particularly preferred embodiment, y is equal to 0.008.

According to at least one further embodiment, the molar fraction z of Mn is equal to or greater than 0.010, or equal to or greater than 0.015, or equal to or greater than 0.020. Furthermore the molar fraction z of Mn can be equal to or smaller than 0.050, or equal to or smaller than 0.040, or equal to or smaller than 0.035, or equal to or smaller than 0.030. In a particularly preferred embodiment, z is equal to 0.025.

According to at least one further embodiment, a light-emitting device comprises a light-emitting semiconductor layer sequence and a luminescence conversion element containing a herein-described phosphor with the material Ca(Al_{12-x-y-z}MgₓGe_{y})O₁₉:(zMn⁴⁺). The light-emitting semiconductor layer sequence has an active region for generating light and can, for example, be embodied as a light-emitting semiconductor chip with an epitaxially grown semiconductor layer sequence. Thus, the light-emitting device can be embodied as a light-emitting diode with the herein-described phosphor.

For example, the light-emitting semiconductor layer sequence can be embodied on the basis of InGaAlN. InGaAlN-based semiconductor layer sequences and InGaAlN-based light-emitting semiconductor chips include, in particular, a semiconductor layer sequence composed of different individual layers and containing at least one individual layer comprising a material from the III-V compound semiconductor material system InₓAl_{y}Ga_{1-x-y}N where 0≦x≦1, 0≦y≦1 and x+y≦1. A light-emitting chip having a semiconductor layer sequence with at least one active region based on InGaAlN can, for example, preferably emit electromagnetic radiation in an ultraviolet to green wavelength range.

According to at least one further embodiment, the luminescence conversion element can be formed as at least one layer or platelet, which comprises or consists of the phosphor and which is arranged in a beam path of the light generated by the light-emitting semiconductor layer sequence. For example, the phosphor can be arranged as powder in a matrix material, wherein the matrix material can be a plastic material or a ceramic material. Alternatively, the phosphor itself can be formed as a solid or powder-like layer or as a platelet.

According to at least one further embodiment, the luminescence conversion element further comprises an additional phosphor that preferably converts light in an ultraviolet to blue spectral region to light in a green to yellow spectral region. For example, the additional phosphor can comprise Y₃Al₅O₁₂:Ce (YAG:Ce). YAG:Ce can be very advantageous as the additional phosphor, since it can meet most of the technical requirements for LED applications. However, YAG:Ce, in connection with an ultraviolet to blue light-emitting semiconductor layer sequence, cannot be used for generating warm-white light with a high color-rendering index (CRI). Therefore, a red emitting phosphor in the form of the herein-described phosphor can be used in combination with YAG:Ce in order to produce warm-white light.

In contrast to the herein-described phosphor with the material Ca(Al_{12-x-y-z}MgₓGe_{y})O₁₉:(zMn⁴⁺), other red emitting phosphors, which are known in the art, have several drawbacks in comparison with the herein-described phosphor: Nitride and oxynitride based red phosphors, which can be excited by blue light and even can exhibit a high performance under the usual working conditions of LED applications, have the disadvantage that the synthesis processes are complex and need high temperatures and pressures. Furthermore, such phosphors are quite expensive. Silicate based red phosphors usually emit light at a wavelength below 600 nm and therefore in a spectral region to which the human eye is not very sensitive. Furthermore, it can be difficult to produce such phosphors with an excitation wavelength in a blue spectral region as, for example, around 460 nm. Mn⁴⁺ doped fluoride phosphors are usually not very stable and are toxic to the environment.

### BRIEF DESCRIPTION OF THE DRAWINGS

Further features, advantages and expediencies will become apparent from the following description of exemplary embodiments in conjunction with the figures.

FIG. 1 shows schematic views of method steps of a method for producing a phosphor according to an embodiment.

FIGS. 2 to 4 show experimental results of phosphor samples according to further embodiments.

FIG. 5 shows a schematic view of light-emitting device with a phosphor according to a further embodiment.

Components that are identical, of identical type and/or act identically are provided with identical reference symbols in the figures.

### DETAILED DESCRIPTION OF ILLUSTRATIVE EMBODIMENTS

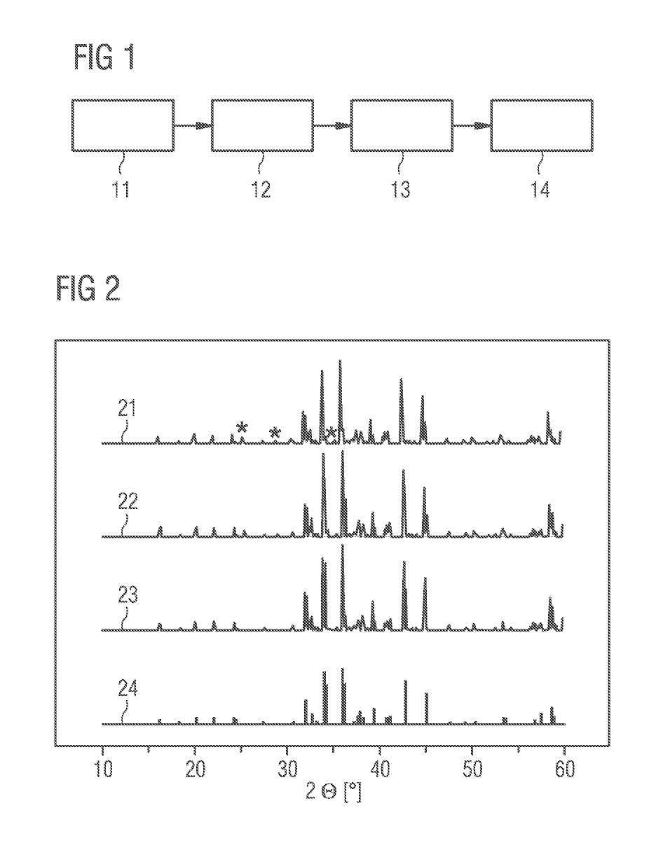

In FIG. 1, an embodiment of a method for producing a phosphor comprising Ca(Al_{12-x-y-z}MgₓGe_{y})O₁₉:(zMn⁴⁺) with 0<x, y, z<1 is shown.

In a first method step 11, high purity Al(OH)₃, CaCO₃, Mg(OH)₂.4MgCO₃.6H₂O, MnO₂ and GeO₂ are provided as raw materials. The raw materials are weighted and provided in respective amounts according to their respective fractions in the finished phosphor.

In a further method step 12, the raw materials are formed to a powder by milling in a crucible such as, for example, an agate crucible. In order to provide a well-mixed powder of the raw materials, the milling can be performed, for example, for more than 30 minutes.

Afterwards, the mixed powder of the raw materials is moved into a heat-resistant crucible such as, for example, an Al₂O₃ crucible and put into a furnace so that, in a further method step 13, the raw materials are heated to a target temperature of equal to or more than 1500° C., preferably of equal to or more than 1550° C. and particularly preferably of equal to or more than 1600° C. When the heating temperature reaches the target temperature, the temperature is kept stable and the mixed powder is fired for a sufficiently long time, for example for about 4 hours, during which, as a final product, the phosphor is formed.

In a further method step 14, which may also be omitted, the product can be milled to form a phosphor powder.

The phosphor produced by the described method comprises and preferably consists of the material Ca(Al_{12-x-y-z}MgₓGe_{y})O₁₉:(zMn⁴⁺) with 0<x, y, z<1. Depending on the provided relative amounts of the raw materials, the parameters x, y and z preferably lie in the following ranges:
0<x≦0.10 or 0.01≦x≦0.08 or 0.02≦x≦0.06 or 0.03≦x≦0.05 or x=0.04;
0<y<0.016 or 0.001≦y≦0.015 or 0.002≦y≦0.012 or 0.004≦y≦0.012 or 0.005≦y≦0.010 or 0.007≦y≦0.009 or y=0.008.
0<z≦0.050 or 0.010≦z≦0.040 or 0.015≦z≦0.035 or 0.020≦z≦0.030 or z=0.025.

FIGS. 2 to 4 show experimental measurements of phosphor samples comprising the material Ca(Al_{12-x-y-z}MgₓGe_{y})O₁₉:(zMn⁴⁺) and being produced by the method described before, wherein various manufacturing parameters were varied.

In FIG. 2, x-ray diffraction (XRD) measurements 21, 22 and 23 of different samples of phosphors with the material Ca(Al_{11.927}Mg_{0.04}Ge_{0.008})O₁₉:(0.025Mn⁴⁺), i.e., with the parameters x=0.04, y=0.008 and z=0.025, are shown, wherein the different samples were produced at different firing temperatures. For comparison, the JCPDS (Joint Committee on Powder Diffraction Standards) standard for CaAl₁₂O₁₉ (38-04790) is also shown and marked with reference numeral 24. The measurements 21, 22 and 23 belong to powder samples, which were fired for 4 hours at temperatures of 1500° C., 1550° C. and 1600° C., respectively.

In the measurement 21 of the phosphor sample fired at a target temperature of 1500° C., Al₂O₃ diffraction peaks, which are marked with the asterisks (*), can be identified, which suggest the presence of a second phase formed by Al₂O₃. While the Al₂O₃ second phase peaks are already smaller in the measurement 22 of the phosphor sample fired at a target temperature of 1550° C., no indication of a second phase can be found in measurement 23 of the phosphor sample fired at a target temperature of 1600° C., which indicates that the phosphor was produced in a single, i.e., pure, phase.

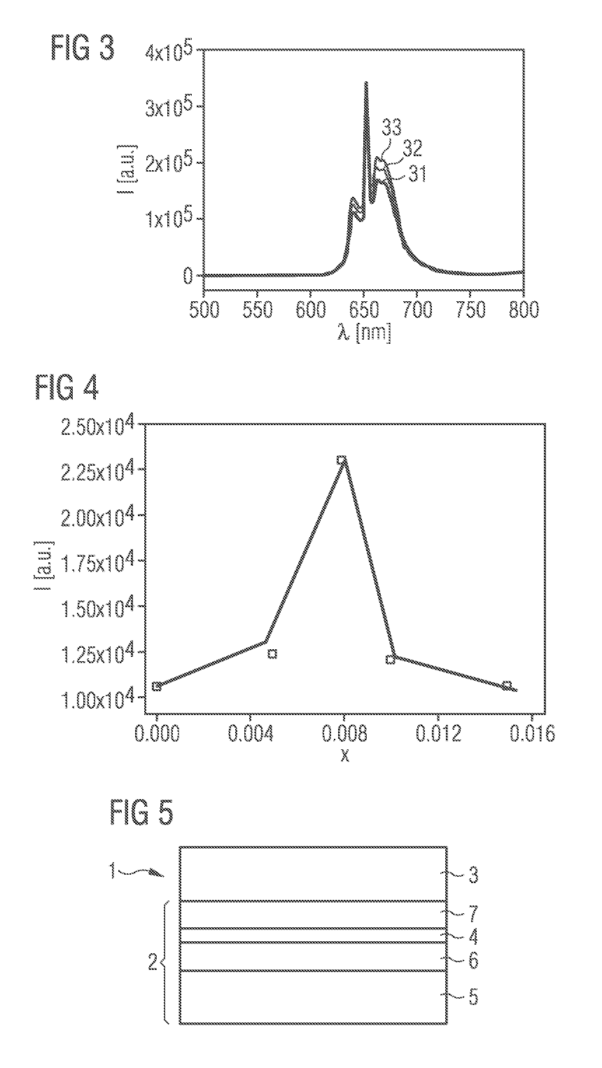

FIG. 3 shows measurements 31, 32, 33 of the respective emission intensity I (in arbitrary units) of several phosphor samples with the material Ca(Al_{11.927}Mg_{0.04}Ge_{0.008})O₁₉:0.025Mn⁴⁺, wherein the different samples were again produced at different firing temperatures. As described for the measurements shown in FIG. 2, the measurements 31,32, 33 belong to powder samples, which were fired for 4 hours at temperatures of 1500° C., 1550° C. and 1600° C., respectively. The excitation wavelength was 460 nm.

The highest luminescent intensity was reached for the sample fired at a temperature of 1600° C. Thus, the higher phase purity of the sample belonging to the measurement 33 leads to a higher performance.

As the conversion performance of a phosphor increases with increasing purity, a firing temperature of 1600° C. and a heating time of 4 hours were chosen for the measurement shown in FIG. 4 for producing the examined phosphor samples.

FIG. 3 shows measurements which are the results of the emission intensity I (in arbitrary units) of several phosphor samples with different Ge concentrations x, shown on the horizontal axis. In particular, phosphor samples were produced with the material Ca(Al_{12-x-y-z}MgₓGe_{y})O₁₉:zMn⁴⁺ with x=0.04 and z=0.025, whereas the Ge concentration y was chosen to be 0.005, 0.008, 0.010 and 0.015. For comparison, a Ge-free phosphor sample, i.e., a phosphor with y=0, was also investigated. It can be seen that for a Ge concentration of 0.005, the emission intensity of the phosphor increases by about 25%. Furthermore, for x=0.008 When y=0.005, the relative emission intensity of the phosphor increases dramatically by a factor of more than 2.2. On the other hand, the emission intensity of the phosphor sample with a Ge concentration of about 0.016 is nearly the same as the emission intensity of the Ge-free sample, whereas for a Ge concentration of 0.010 the relative emission intensity is about the same as for a Ge concentration of 0.005. The quantum efficiency of the best sample was measured to be as high as 46%. This value is, for example, higher than the quantum efficiency of about 45% of commercially available fluoride-based phosphors with the material 3.5MgO.0.5MgF2.GeO₂ doped with Mn⁴⁺, measured under similar conditions, so that the phosphor described herein can be used to replace the commercially available phosphor. Moreover, the phosphor described herein is much less cost-intensive than the commercially available phosphor.

The measurements shown in FIGS. 2 to 4 clearly show that, in particular, by the introduction of Ge atoms in the crystal lattice of the phosphor described herein and by choosing suitable manufacturing conditions the phosphor performance can be significantly increased compared to phosphors known in the art. Furthermore, the introduction of Ge into the crystal lattice does not change the solid state phase compared to an unmodified CaAl₁₂O₁₉:Mn⁴⁺ phosphor, which indicates that the phosphor described herein is a solid solution. A comparison of the excitation spectrum and the emission spectrum of the phosphor described herein with the respective spectra of an unmodified CaAl₁₂O₁₉:Mn⁴⁺ phosphor shows that neither spectrum changes with regard to the relative intensities and positions of the peaks due to the addition of Ge into the crystal lattice, so that there is no blue or red shift of the spectra. Hence, the spectral properties of the herein-described phosphor are independent of the disclosed Ge concentrations and the phosphor described herein can still be excited by blue light and can emit light in the deep red spectral region, whereas the conversion performance of the phosphor can be increased depending on the Ge concentration. Moreover, the manufacturing method is quite simple, as neither high pressure nor a special atmosphere is needed.

In FIG. 5, a light-emitting device 1 is shown according to a further embodiment. The light-emitting device 1 comprises a light-emitting semiconductor layer sequence 2 and a luminescence conversion element 3 containing a herein-described phosphor with the material Ca(Al_{12-x-y-z}MgₓGe_{y})O₁₉:(zMn⁴⁺) with 0<x, y, z<1. In particular, the luminescence conversion element 3 can comprise a phosphor, as discussed in connection with the foregoing figures and embodiments.

The light-emitting semiconductor layer sequence 2 has an active region 4 for generating light and can, for example, be embodied as a light-emitting semiconductor chip with an epitaxially grown semiconductor layer sequence. In particular, the light-emitting device 1 can be embodied as a light-emitting diode with the herein-described phosphor.

The light-emitting semiconductor layer sequence 2 is based on the III-V compound semiconductor material system InₓAl_{y}Ga_{1-x-y}N with 0≦x≦1, 0≦y≦1 and x+y≦1 and is embodied to emit ultraviolet to green light. In particular, the light-emitting semiconductor layer sequence 2 can be embodied to emit blue light, for example with a wavelength of about 460 nm.

The light-emitting semiconductor layer sequence can furthermore comprise a substrate 5, on which semiconductor layers are deposited. The substrate 5 can, for example, comprise an electrically insulating material or a semiconductor material, for instance a compound semiconductor material system as mentioned above. For example, the substrate can comprise sapphire, GaAs, GaP, GaN, InP, SiC, Si and/or Ge or be composed of such a material.

The semiconductor layer sequence 2 can have as active region 4 a layer or a layer stack forming a conventional pn junction, a double heterostructure, a single quantum well structure (SQW structure) or a multiple quantum well structure (MQW structure). Furthermore, the semiconductor layer sequence 2 can comprise further undoped, n-doped and p-doped semiconductor layers, of which layers 6 and 7 are shown purely exemplarily, as well as electrodes, passivation layers and optical layers, for example, which are not discussed in detail, since the general structure of a light-emitting semiconductor layer sequence is known to a person skilled in the art.

In the embodiment shown in FIG. 5, the luminescence conversion element 3 is formed as a layer or platelet, which comprises or consists of the herein described phosphor and which is arranged in a beam path of the light generated by the light-emitting semiconductor layer sequence 2. In particular, the layer- or platelet-shaped luminescence conversion element 3 is directly deposited on the light-emitting semiconductor layer sequence 2. For example, the luminescence conversion element 3 is arranged as a layer or platelet containing the phosphor as powder in a matrix material, wherein the matrix material can be a plastic material or a ceramic material. Alternatively, the phosphor itself can, for example, be a solid or powder-like layer or platelet. Furthermore, the luminescence conversion element 3 can be formed as a casting enclosing the light-emitting semiconductor layer sequence 2, wherein in this case the luminescence conversion element 3 preferably comprises a plastic matrix material containing a phosphor powder. The luminescence conversion element 3 can also be remote from the light-emitting semiconductor layer sequence 2.

Furthermore, the luminescence conversion element 3 can comprise an additional phosphor that, for example, converts light produced by the light-emitting semiconductor layer sequence 2 to light in a green to yellow spectral region. In particular, the additional phosphor can comprise Y₃Al₅O₁₂:Ce (YAG:Ce). A combination of the herein-described red emitting phosphor, a green to yellow emitting additional phosphor such as, for example, YAG:Ce and a blue light-emitting semiconductor layer sequence can be very suitable for producing warm-white light. The additional phosphor can be contained in an additional luminescence conversion element or can be contained together with the herein-described phosphor in the luminescence conversion element 3.

Alternatively or additionally to the features described in connection with the figures, the embodiments shown in the figures can comprise further features described in the general part of the description. Moreover, features and embodiments of the figures can be combined with each other, even if such a combination is not explicitly described.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

1-16. (canceled)

17. A phosphor comprising:
Ca(Al_{12-x-y-z}MgₓGe_{y})O₁₉:(zMn⁴⁺), wherein 0<x, y, z<1.

18. The phosphor according to claim 17, wherein the phosphor consists of Ca(Al_{12-x-y-z}MgₓGe_{y})O₁₉:(zMn⁴⁺), wherein 0<x, y, z<1.

19. The phosphor according to claim 17, wherein 0<y<0.016.

20. The phosphor according to claim 17, wherein 0.005≦y≦0.010.

21. The phosphor according to claim 17, wherein 0<x≦0.10.

22. The phosphor according to claim 17, wherein 0.02<x≦0.08.

23. The phosphor according to claim 17, wherein 0<z≦0.050.

24. The phosphor according to claim 17, wherein x=0.04, y=0.008 and z=0.025.

25. The phosphor according to claim 17, wherein the phosphor is a single phase material.

26. A light-emitting device comprising:
a light-emitting semiconductor layer sequence comprising an active region for generating light; and
a luminescence conversion element containing a phosphor according to claim 17.

27. The light-emitting device according to claim 26, wherein the luminescence conversion element is arranged as at least one layer or platelet in a beam path of a light generated by the light-emitting semiconductor layer sequence.

28. The light-emitting device according to claim 26, wherein the luminescence conversion element further comprises Y₃Al₅O₁₂:Ce.

29. A method for producing a phosphor according to claim 17, wherein Al(OH)₃, CaCO₃, Mg(OH)₂.4MgCO₃.6H₂O, MnO₂ and GeO₂ are provided as raw materials and the raw materials are heated together at a temperature of at least 1500° C.

30. The method according to claim 29, wherein the temperature is at least 1550° C.

31. The method according to claim 29, wherein the temperature is at least 1600° C.

32. The method according to claim 29, wherein the raw materials are provided as mixed powder before heating.
